(19) United States
(12) Patent Application Publication
(10) Pub. No.: US 2008/0001282 A1
(43) Pub. Date: Jan. 3, 2008

(54) Microelectronic assembly having a periphery seal around a thermal interface material

(76) Inventors: Mitul Modi, Phoenix, AZ (US); Sudarshan V. Rangaraj, Chandler, AZ (US); Shankar Ganapathysubramanian, Phoenix, AZ (US); Richard J. Harries, Chandler, AZ (US); Sankara J. Subramanian, Chandler, AZ (US)

Correspondence Address: Stephen M. De Klerk;BLAKELY, SOKOLOFF, TAYLOR & ZAFMAN LLP, Seventh Floor, 12400 Wilshire Boulevard, Los Angeles, CA, 90025, US

(21) Appl. No.: 11/479,258

(22) Filed: Jun. 30, 2006

(51) Int. Cl. H01L 23/10

(52) U.S. Cl. 257/710

(57) ABSTRACT

A microelectronic assembly is provided, comprising at least a first microelectronic die carrying a microelectronic circuit, at least a first periphery seal attached to an edge of a surface of the microelectronic die, at least a first solder thermal interface material attached to a central region of the surface of the microelectronic die, the solder thermal interface material having a higher thermal conductivity than the periphery seal, and a thermally conductive member attached to the periphery seal and the solder thermal interface material on a side thereof opposing the microelectronic die.

### BACKGROUND OF THE INVENTION

1). Field of the Invention

This invention relates to a microelectronic assembly and to a method of constructing a microelectronic assembly.

2). Discussion of Related Art

Integrated circuits are usually formed in and on a semiconductor wafer, and the wafer is subsequently “singulated” or “diced” into individual dies, each die carrying a respective integrated circuit. Such a die is then mounted to a carrier substrate, typically a package substrate, for purposes of structural support and providing electric signals, power, and ground to the integrated circuit. A die may, for example, be mounted to a package substrate by way of bumps that are formed on contacts of the die.

Operation of the integrated circuit causes it to heat up, and it is often required to have a heat-removal system or mechanism in place to prevent overheating of the integrated circuit and its failure. Such a mechanism or system often includes an integrated heat spreader having a thermally conductive component that is placed close to a surface of the die opposing the integrated circuit. A thermal interface material is located between the thermally conductive component and the surface of the die. The thermal interface material is chosen because of its high thermal conductivity. The thermal interface material also attaches on opposing sides to the surface of the integrated circuit and to the thermally conductive member. The intent of such attachment is to reduce thermal resistance between the die and the thermally conductive component.

The components of a microelectronic assembly of the above kind have different coefficients of thermal expansion so that thermally induced stresses are created when the microelectronic assembly heats up or cools down. Such stresses can cause creep in the thermal interface material. Such stresses can also cause delamination between the thermal interface material and either the thermally conductive component or the die, because their magnitude may be larger than what can be tolerated by the interfaces, or because of fatigue stresses. These stresses also tend to be the highest near a periphery of the die.

### BRIEF DESCRIPTION OF THE DRAWINGS

The invention is described by way of examples with reference to the accompanying drawings, wherein:

FIG. 1 is a cross-sectional side view of some components of a microelectronic assembly, according to an embodiment of the invention;

FIG. 2 is a plan view of the components of FIG. 1;

FIG. 3 is a view similar to FIG. 1 after a solder thermal interface material is located on a microelectronic die shown in FIG. 1;

FIG. 4 is a view similar to FIG. 3 after an integrated heat spreader is located over the solder thermal interface material to complete the components of the microelectronic assembly;

FIG. 5 is a top plan view of a microelectronic assembly, according to another embodiment of the invention, having multiple microelectronic dies;

FIG. 6 is a cross-sectional side view of the microelectronic assembly of FIG. 5; and

FIG. 7 is a block diagram of a computer system that can include the microelectronic assembly.

### DETAILED DESCRIPTION OF THE INVENTION

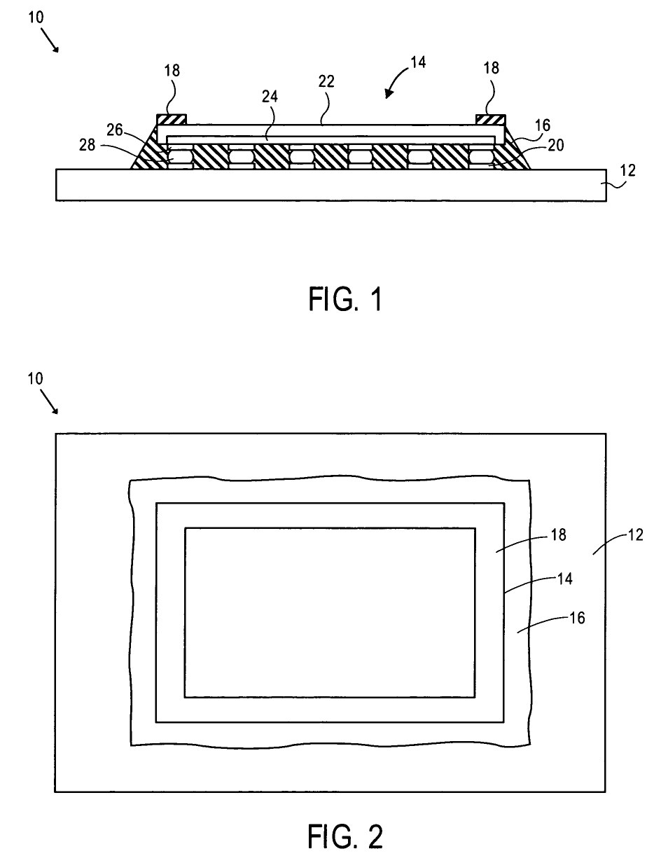

FIGS. 1 and 2 of the accompanying drawings illustrate a partially constructed microelectronic assembly 10, according to an embodiment of the invention. The microelectronic assembly 10 includes a carrier substrate 12, a microelectronic die 14, an underfill material 16, and a periphery seal 18.

The carrier substrate 12 is typically a package substrate that is made of alternating dielectric layers and metal layers (not shown). The metal layers are patterned to form conductive lines. The carrier substrate 12 further has plugs and vias that connect metal lines of different levels to one another. The carrier substrate 12 also has a plurality of terminals 20 on an upper surface, and a plurality of contacts (not shown) for connecting the carrier substrate 12 to another substrate such as a motherboard or a computer card. The terminals 20 and the contacts of the carrier substrate 12 are also connected to the metal lines formed within the carrier substrate 12.

The microelectronic die 14 includes a semiconductor substrate 22, an integrated circuit 24, contacts 26, and conductive bumps 28. The integrated circuit 24 is formed in and on a lower surface of the semiconductor substrate 22. The integrated circuit 24 includes a large number (typically millions) of electronic components such as transistors, and further includes a plurality of alternating metal and dielectric layers. The metal layers of the integrated circuit 24 are patterned into metal lines, and the metal lines of different levels are connected to one another with metal plugs and vias. The contacts 26 are formed on a lower surface of the integrated circuit 24, and are also connected to the metal lines of the integrated circuit 24. The conductive bumps 28 are formed on the contacts 26, utilizing an electroplating operation.

The conductive bumps 28 are placed on the terminals 20. The entire assembly, including the microelectronic die 14 and the carrier substrate 12, is inserted into an oven at a temperature sufficiently high that the bumps 28 reflow and attach to the terminals 20 according to a process commonly known as “Controlled Collapse Chip Connect” (C4). The assembly 10 is then allowed to cool, which causes solidification of the bumps 28.

The underfill material 16 is made of a polymer. The underfill material 16 is introduced at an edge of the microelectronic die 14 and flows into a cavity between the microelectronic die 14 and the carrier substrate 12 under capillary action. The underfill material 16 envelopes the bumps 28, but at this stage is not cured and cannot provide rigidity to protect the bumps 28 from delaminating off the terminals 20 or the contacts 26.

The periphery seal 18 is subsequently placed on an upper surface of the microelectronic die 14. The periphery seal 18 is typically made of the same polymer material as the underfill material 16. Referring specifically to FIG. 2, it can be seen that the periphery seal 18 is in the form of a square or rectangular ring. An outer profile of the periphery seal 18 matches an outer profile of the upper surface of the microelectronic die 14. An inner profile of the periphery seal 18 is located on the upper surface of the microelectronic die 14 and spaced from an edge of the upper surface of the microelectronic die 14. The periphery seal 18 has a width that is between five and ten percent of a width of the upper surface of the microelectronic die 14.

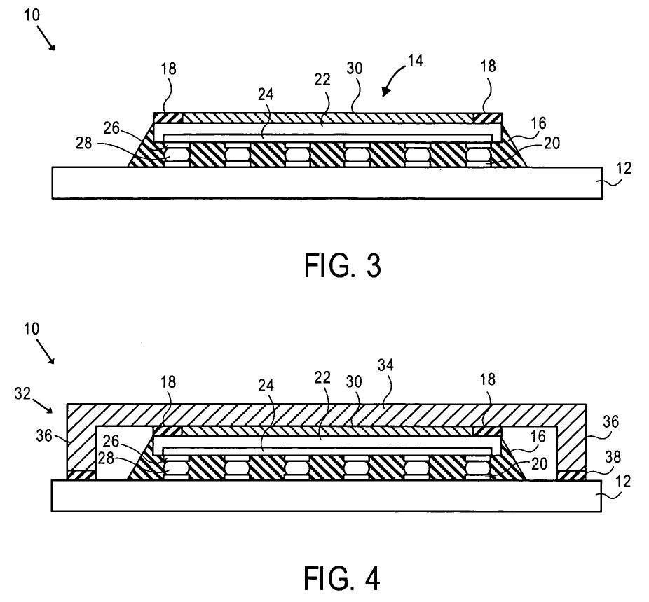

Referring now to FIG. 3, a solder thermal interface material 30 is dispensed on a central region of the upper surface of the microelectronic die 14. The solder thermal interface material 30 extends up to an inner edge of the periphery seal 18. The solder thermal interface material 30 is approximately as thick as the periphery seal 18, so that upper surfaces of the solder thermal interface material 30 and the periphery seal 18 are substantially in the same horizontal plane. The solder thermal interface material 30 is chosen for its high thermal conductivity, and typically has a thermal conductivity that is at least two times a thermal conductivity of the periphery seal 18. The solder thermal interface material 30 also covers a majority of the upper surface of the microelectronic die 14. The solder thermal interface material 30 is typically made of pure indium. The periphery seal 18 can be made of Dow Corning EA-625 Micro Lid Sealant or Shin Etsu 5690C.

Referring now to FIG. 4, an integrated heat spreader 32 is subsequently placed over the microelectronic die 14, the periphery seal 18, and the solder thermal interface material 30. The integrated heat spreader 32 has a thermally conductive member 34 having a lower surface that rests on upper surfaces of the periphery seal 18 and the solder thermal interface material 30, and has sides 36 extending downward from outer edges of the thermally conductive member 34. The integrated heat spreader 32 and a heat spreader seal 38 form the final components of the microelectronic assembly 10. The heat spreader seal 38 is located between a lower surface of each one of the sides 36 and an upper surface of the carrier substrate 12.

All the components of the microelectronic assembly 10 of FIG. 4 are then inserted into an oven. The oven is at a temperature sufficiently high so that the solder thermal interface material 30 melts or liquefies. The microelectronic assembly 10 is also held in the oven sufficiently long so that the underfill material 16, the periphery seal 18, and the heat spreader seal 38 cure. Curing causes hardening of the underfill material 16, the periphery seal 18, and the heat spreader seal 38. The periphery seal 18 attaches itself to the upper surface of the microelectronic die 14 and to a lower surface of the thermally conductive member 34. The entire assembly 10 is then allowed to cool, which causes solidification of the solder thermal interface material 30 and attachment of the solder thermal interface material 30 to the upper surface of the microelectronic die 14 and the lower surface of the thermally conductive member 34.

A more brittle interface is formed between the periphery seal 18 and the thermally conductive member 34 than between the solder thermal interface material 30 and the thermally conductive member 34. The solder thermal interface material 30 is susceptible to creep and plastic deformation. Because of a stronger, more brittle interface between the periphery seal 18 and the thermally conductive member 34, and because of material properties of the periphery seal 18, the periphery seal 18 can tolerate a greater thermally induced stress than the solder thermal interface 30 without delaminating from either the thermally conductive member 34 or the microelectronic die 14. The periphery seal 18 can also tolerate a larger number of stress cycles than the solder thermal interface material 30, without creep or fatigue-related plastic deformation.

It can thus be seen that the combination of the solder thermal interface material 30 and the periphery seal 18 provides an interface that has a high thermal conductivity due to the high thermal conductivity of the solder thermal interface material 30, yet strong because of (i) the material of the periphery seal 18, (ii) the more brittle interface between the periphery seal 18 and the thermally conductive member 34, and (iii) because of the location of the periphery seal 18 on the periphery of the upper surface of the microelectronic die 14 where stress concentrations tend to be the highest.

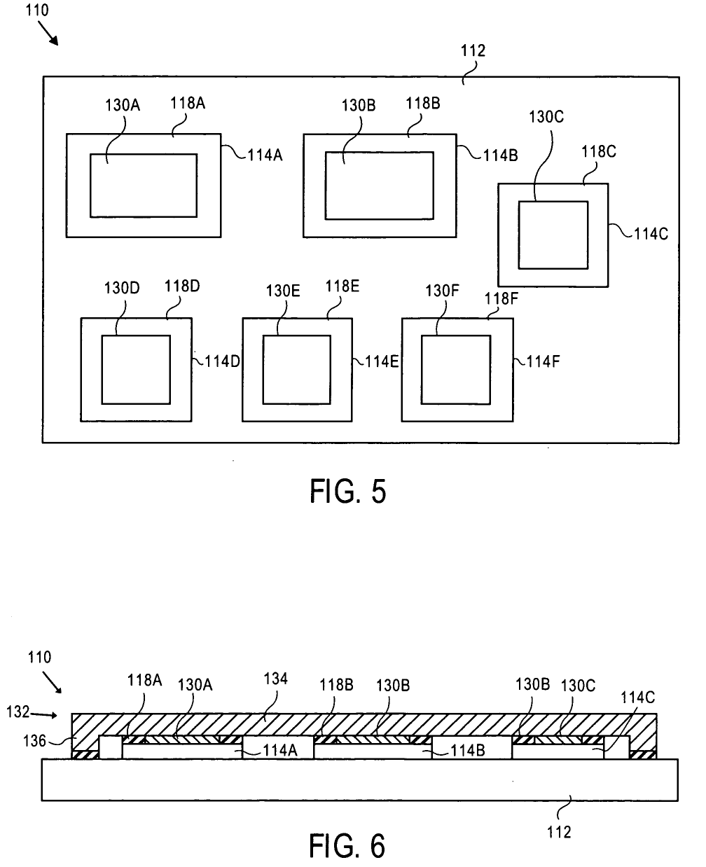

FIGS. 5 and 6 illustrate a microelectronic assembly 110 according to an alternative embodiment of the invention. The microelectronic assembly 110 has a carrier substrate 112, a plurality of microelectronic dies 114A-F, a plurality of periphery seals 118A-F, and a plurality of solder thermal interface materials 130A-F. The microelectronic dies 114A-F are mounted to the carrier substrate 112 in a manner similar to the manner by which the microelectronic die 14 of FIG. 1 is mounted to the carrier substrate 12. A respective one of the periphery seals 118A-F is located on a respective one of the microelectronic dies 114A-F, and a respective one of the solder thermal interface materials 130A-F is located on a respective one of the microelectronic dies 114A-F.

With specific reference to FIG. 6, the microelectronic assembly 110 further includes an integrated heat spreader 132 having a thermally conductive member 134 and side portions 136. The thermally conductive member 134 is in contact with all of the periphery seals 118A-F and all of the solder thermal interface materials 130A-F. The components of the microelectronic assembly 110 are secured to one another in a manner similar to the manner that by which the components of the microelectronic assembly 10 of FIG. 4 are secured to one another.

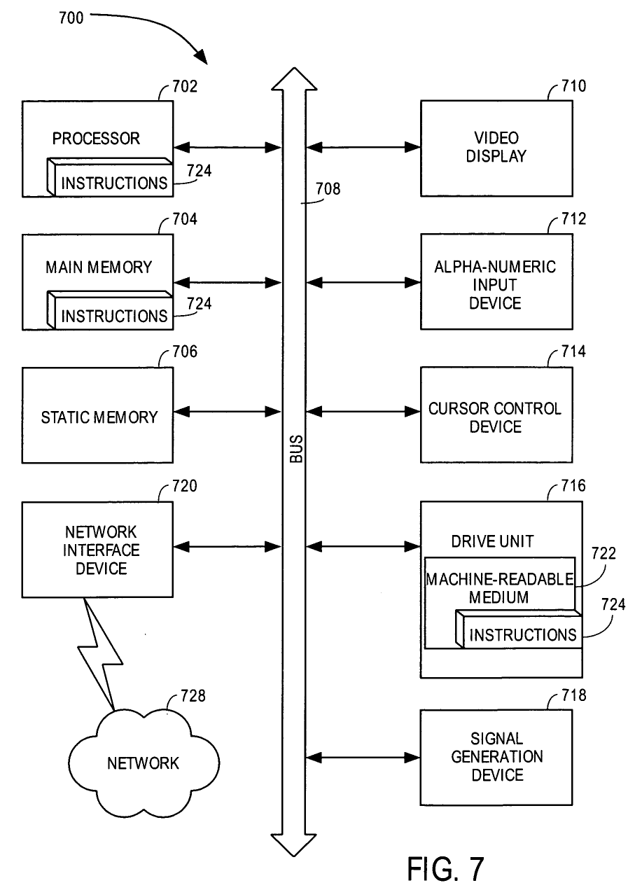

FIG. 7 shows a diagrammatic representation of a machine in the exemplary form of a computer system 700 within which a set of instructions, for causing the machine to perform any one or more of the methodologies discussed herein, may be executed. In alternative embodiments, the machine operates as a standalone device or may be connected (e.g., networked) to other machines. In a networked deployment, the machine may operate in the capacity of a server or a client machine in a server-client network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The exemplary computer system 700 includes a processor 702 (e.g., a central processing unit (CPU), a graphics processing unit (GPU) or both), a main memory 704 (e.g., read only memory (ROM), flash memory, dynamic random access memory (DRAM) such as synchronous DRAM (SDRAM) or Rambus DRAM (RDRAM), etc.), and a static memory 706 (e.g., flash memory, static random access memory (SRAM), etc.), which communicate with each other via a bus 708.

The computer system 700 may further include a video display 710 (e.g., a liquid crystal display (LCD) or a cathode ray tube (CRT)). The computer system 700 also includes an alpha-numeric input device 712 (e.g., a keyboard), a cursor control device 714 (e.g., a mouse), a disk drive unit 716, a signal generation device 718 (e.g., a speaker), and a network interface device 720.

The disk drive unit 716 includes a machine-readable medium 722 on which is stored one or more sets of instructions 724 (e.g., software) embodying any one or more of the methodologies or functions described herein. The software may also reside, completely or at least partially, within the main memory 704 and/or within the processor 702 during execution thereof by the computer system 700, the main memory 704 and the processor 702 also constituting machine-readable media.

The software may further be transmitted or received over a network 728 via the network interface device 720.

While the machine-readable medium 724 is shown in an exemplary embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying a set of instructions for execution by the machine and that cause the machine to perform any one or more of the methodologies of the present invention. The term “machine-readable medium” shall accordingly be taken to include, but not be limited to, solid-state memories, optical and magnetic media, and carrier wave signals.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

What is claimed:

1. A microelectronic assembly, comprising:
at least a first microelectronic die carrying a microelectronic circuit;
at least a first periphery seal attached to an edge of a surface of the microelectronic die;
at least a first solder thermal interface material attached to a central region of the surface of the microelectronic die, the solder thermal interface material having a higher thermal conductivity than the periphery seal; and
a thermally conductive member attached to the periphery seal and the solder thermal interface material on a side thereof opposing the microelectronic die.

2. The microelectronic assembly of claim 1, wherein the thermal conductivity of the solder thermal interface material is at least twice the thermal conductivity of the periphery seal.

3. The microelectronic assembly of claim 1, wherein the solder thermal interface material is made of indium.

4. The microelectronic assembly of claim 1, wherein the periphery seal is a polymer.

5. The microelectronic assembly of claim 1, wherein the periphery seal can tolerate a larger magnitude of stress than the solder thermal interface material.

6. The microelectronic assembly of claim 5, wherein the periphery seal has less creep than the solder thermal interface material.

7. The microelectronic assembly of claim 5, wherein the periphery seal has less plastic deformation than the solder interface material.

8. The microelectronic assembly of claim 1, wherein the periphery seal can tolerate a larger number of stress cycles than the solder thermal interface material.

9. The microelectronic assembly of claim 8, wherein the periphery seal has less creep than the solder thermal interface material.

10. The microelectronic assembly of claim 8, wherein the periphery seal has less plastic deformation than the solder interface material.

11. The microelectronic assembly of claim 1, wherein the periphery seal forms a more brittle interface with the thermally conductive member than the solder thermal interface material.

12. The microelectronic assembly of claim 1, wherein the periphery seal is formed on an entire periphery of the microelectronic die.

13. The microelectronic assembly of claim 1, further comprising:
a carrier substrate, the microelectronic die being mounted to the carrier substrate, with the carrier substrate and the solder thermal interface material on opposing sides of the microelectronic die.

14. The microelectronic assembly of claim 1, further comprising:
at least a second microelectronic die, at least a second periphery seal attached to an edge of a surface of the second microelectronic die; and
at least a second solder thermal interface material on a surface of the second microelectronic die, the thermally conductive member being attached to the second periphery seal and the second solder thermal interface material.

15. A microelectronic assembly, comprising:
a carrier substrate;
first and second microelectronic dies mounted to the carrier substrate;
first and second periphery seals attached to an edge of a surface of the first and second microelectronic dies, respectively;
first and second solder thermal interface materials attached to surfaces of the first and second microelectronic dies, respectively; and
a thermally conductive member attached to the periphery seals and the solder interface materials.

16. The microelectronic assembly of claim 15, wherein the solder thermal interface materials are made of indium and the periphery seals are made of a polymer.

17. The microelectronic assembly of claim 15, wherein each periphery seal is located on an entire periphery of a respective one of the microelectronic dies.

18. A method of constructing a microelectronic assembly, comprising:
attaching a periphery seal to an edge of a surface of a microelectronic die;
attaching a solder thermal interface material to a central region of the surface of the microelectronic die, the solder thermal interface material having a higher thermal conductivity than the periphery seal; and
attaching a thermally conductive member to the periphery seal and the solder thermal interface material.

19. The method of claim 18, wherein the thermal conductivity of the solder thermal interface material is at least two times the thermal conductivity of the periphery seal.

20. The method of claim 18, wherein the periphery seal is made of a polymer and the solder thermal interface material is made of indium.
